(19) United States
(12) Patent Application Publication
(10) Pub. No.: US 2025/0389024 A1
(43) Pub. Date: Dec. 25, 2025

(54) APPARATUS FOR TREATING SUBSTRATE

(71) Applicant: Samsung Electronics Co., Ltd., Suwon-si (KR)

(72) Inventors: Dongho SHIN, Suwon-si (KR); Seungjae KIM, Suwon-si (KR); Oh-Hyuk KWON, Suwon-si (KR); Eung-Su KIM, Suwon-si (KR); Yihwan KIM, Suwon-si (KR); Eun-Kyung HONG, Suwon-si (KR)

(73) Assignee: Samsung Electronics Co., Ltd., Suwon-si (KR)

(21) Appl. No.: 18/990,414

(22) Filed: Dec. 20, 2024

(30) Foreign Application Priority Data
Jun. 20, 2024 (KR) 10-2024-0080482

(51) Int. Cl. C23C 16/52; C23C 16/44; C23C 16/455

(52) U.S. Cl. CPC C23C 16/52; C23C 16/4412; C23C 16/45544

(57) ABSTRACT

Provided is a substrate treating apparatus including a chamber including an internal space for processing a substrate, and a gas inlet and a gas outlet configured to be intercommunicated with the internal space, a gas supply pipe connected to the gas inlet, a gas controller configured to regulate a supply gas to the internal space of the chamber through the gas supply pipe, a gas exhaust pipe connected to the gas outlet, a vacuum pump configured to pump gas from the internal space of the chamber through the gas exhaust pipe, a plurality of valves in series in the gas exhaust pipe configured to open at least a portion of the gas exhaust pipe between the chamber and the vacuum pump, and a valve controller configured to regulate a degree of opening for each valve of the plurality of valves.

### CROSS-REFERENCE TO RELATED APPLICATION(S)

This application claims the benefit of Korean Patent Application No. 10-2024-0080482, filed on Jun. 20, 2024, in the Korean Intellectual Property Office, the disclosure of which is incorporated herein by reference in its entirety.

### BACKGROUND

Some example embodiments relate to a substrate treating apparatus.

In the process of fabricating a semiconductor device, a deposition process, such as a chemical vapor deposition (CVD) process and an atomic layer deposition (ALD) process may be included. For each deposition process, different internal pressures may be desired in a chamber where the process occurs, thus making pressure control a key element in the deposition process.

Therefore, diverse research continues to be conducted on a substrate treating apparatus in which control of the internal pressure of a chamber may be improved.

### SUMMARY

Some example embodiments provide a substrate treating apparatus in which control of the internal pressure of a chamber may be improved.

Some example embodiments of the present disclosure are not limited to the technical features described above, and other unstated features may be made apparent to those skilled in the art from the following description.

According to some example embodiments, there is provided a substrate treating apparatus including a chamber including an internal space for processing a substrate, and a gas inlet and a gas outlet configured to be intercommunicated with the internal space, a gas supply pipe connected to the gas inlet, a gas controller configured to regulate a supply gas to the internal space of the chamber through the gas supply pipe, a gas exhaust pipe connected to the gas outlet, a vacuum pump configured to pump gas from the internal space of the chamber through the gas exhaust pipe, a plurality of valves in series in the gas exhaust pipe configured to open at least a portion of the gas exhaust pipe between the chamber and the vacuum pump, and a valve controller configured to regulate a degree of opening for each valve of the plurality of valves. The valve controller is configured to vary the degree of opening for each valve of the plurality of valves in response to an amount of the supply gas delivered by the gas controller.

According to some example embodiments, there is provided a substrate treating apparatus including a chamber including an internal space for processing a substrate, and a gas inlet and a gas outlet configured to be intercommunicated with the internal space, a gas supply pipe connected to the gas inlet, a gas controller configured to regulate a supply gas to the internal space of the chamber through the gas supply pipe, a gas exhaust pipe connected to the gas outlet, a vacuum pump configured to pump gas from the internal space of the chamber through the gas exhaust pipe, a plurality of valves in series in the gas exhaust pipe configured to open at least a portion of the gas exhaust pipe between the chamber and the vacuum pump, and a valve controller configured to regulate a degree of opening for each valve of the plurality of valves. In the internal space of the chamber, a plurality of processes are performed simultaneously, the plurality of processes includes a CVD process and an ALD process, the gas controller includes a CVD gas controller configured to control gas in the CVD process, and an ALD gas controller configured to control gas in the ALD process, the CVD gas controller is configured to maintain a constant pressure of gas supplied in the chamber for performing the CVD process, the ALD gas controller is configured to regulate a pressure of gas supplied in the chamber for performing the ALD process, and the valve controller is configured to vary the degree of opening for each valve of the plurality of valves in response to a gas pressure being changed by the ALD gas controller.

According to some example embodiments, there is provided a substrate treating apparatus including a chamber including an internal space for processing a substrate, and a gas inlet and a gas outlet configured to be intercommunicated with the internal space, a gas supply pipe connected to the gas inlet, a gas controller configured to regulate a supply gas to the internal space of the chamber through the gas supply pipe, a gas exhaust pipe connected to the gas outlet, a vacuum pump configured to pump gas from the internal space of the chamber through the gas exhaust pipe, a first valve in the gas exhaust pipe, the first valve configured to open at least a portion of the gas exhaust pipe between the chamber and the vacuum pump, a second valve in series with the first valve, the second valve configured to open at least a portion of the gas exhaust pipe between the chamber and the vacuum pump, and a pressure controller configured to regulate pressure in the internal space of the chamber. The pressure controller includes a pressure sensor configured to measure a pressure in the internal space of the chamber, and a valve controller configured to vary a degree of opening of the second valve in response to a measurement result of the pressure sensor.

Additional aspects of example embodiments will be set forth in part in the description which follows and, in part, will be apparent from the description, or may be learned by practice of the disclosure.

According to some example embodiments, it is possible to facilitate an improvement in controlling the internal pressure of a chamber.

### BRIEF DESCRIPTION OF THE DRAWINGS

These and/or other aspects, features, and advantages of the example embodiments will become apparent and more readily appreciated from the following description of some example embodiments, taken in conjunction with the accompanying drawings of which:

FIG. 1 is a diagram schematically illustrating a substrate treating apparatus according to some example embodiments;

FIG. 2 is a diagram schematically illustrating a gas controller included in a substrate treating apparatus according to some example embodiments;

FIG. 3 is a diagram illustrating a chamber included in a substrate treating apparatus according to some example embodiments;

FIG. 4 is a diagram illustrating a gas supply unit included in a substrate treating apparatus according to some example embodiments;

FIG. 5 is a diagram illustrating a substrate seating unit included in a substrate treating apparatus according to some example embodiments;

FIGS. 6 and 7 are diagrams illustrating a flow of gas in a chamber included in a substrate treating apparatus according to some example embodiments;

FIG. 8 is a diagram illustrating a plurality of valves included in a substrate treating apparatus according to some example embodiments;

FIG. 9 is a flow chart illustrating a relationship between a gas controller and a valve controller included in a substrate treating apparatus according to some example embodiments;

FIG. 10 is a graph illustrating a flow rate change depending on a valve opening position;

FIG. 11 is a diagram illustrating a valve with a 0 percent (%) valve opening position;

FIG. 12 is a diagram illustrating a valve with a 100% valve opening position;

FIGS. 13 and 14 are diagrams illustrating a valve included in a substrate treating apparatus according to some example embodiments;

FIG. 15 schematically illustrates a substrate treating apparatus according to some example embodiments; and

FIG. 16 is a flow chart illustrating a relationship between a pressure sensor and a valve controller included in a substrate treating apparatus according to some example embodiments.

### DETAILED DESCRIPTION

Before describing the following example embodiments in detail, the words and terminologies used in the specification and claims are not to be construed as limited to common or dictionary meanings but construed as meanings and conceptions coinciding with the technical spirit of the present disclosure under a principle that the inventor(s) may appropriately define the conception of the terminologies to explain the disclosure in the optimum manner. Therefore, the example embodiments described in the specification and the configurations illustrated in the drawings do not fully cover the spirit of the present disclosure. Accordingly, it should be understood that there may be various equivalents and modifications to the following example embodiments.

Like reference numerals in each drawing attached to the specification may refer to components or elements performing like functions in substance. For convenience of description and understanding, the same reference numeral may be used for description in different example embodiments. In other words, although elements with the same reference numeral are illustrated in a plurality of drawings, all of the plurality of drawings may not represent one example embodiment.

Hereinafter, the singular used herein includes the plural unless apparently defined otherwise by context. It should be understood that terms such as “comprise or include” and “consist of” are intended to indicate the presence of a feature, a number, a step, an operation, an element, a component, or a combination thereof which are described herein and not intended to previously exclude the possibility of the presence or addition of one or more other features, numbers, steps, operations, elements, components, or combinations thereof.

In addition, expressions such as upper side, upper portion, lower side, lower portion, side surface, front surface, and rear surface hereinafter are represented based on a direction illustrated in a drawing and may be represented otherwise when the direction of a corresponding object changes.

In addition, expressions such as a first direction (D1), a second direction (D2), and a third direction (D3) hereinafter may correspond to x-axis, y-axis, and z-axis directions which define three-dimensional space but are not limited thereto and, as the definition of one direction (for example, the first direction) changes, the other directions (for example, the second direction and the third direction) may change in response thereto.

Furthermore, terms including ordinal numbers such as “first” and “second” may be used to differentiate between elements in the specification and claims. These ordinal numbers may be used to differentiate identical or similar elements from each other, and the use of the ordinal numbers may not limit the meanings of terms. As an example, an element combined with an ordinal number is not to be construed as the using order or arrangement order thereof is limited by the number. In some cases, each ordinal number may also be used by replacing each other.

Hereinafter, some example embodiments of the present disclosure will be described with reference to the accompanying drawings. However, the present disclosure is not limited to the example embodiments described. For example, those of ordinary skill in the art may understand that some example embodiments included in the scope of the present disclosure through the addition, modification, or deletion of elements may also fall within the scope of the present disclosure. The shape or size of elements in drawings may be exaggerated for clearer description.

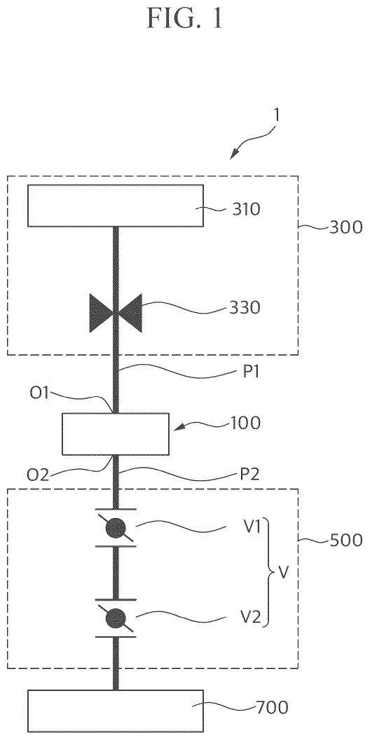

FIG. 1 is a diagram schematically illustrating a substrate treating apparatus 1 according to some example embodiments.

Referring to FIG. 1, the substrate treating apparatus 1 according to some example embodiments may include a chamber 100, a gas supply pipe P1, a gas controller 300, a gas exhaust pipe P2, and a vacuum pump 700.

In the chamber 100 according to some example embodiments, an internal space for treating a substrate through various processes may be formed. In the chamber 100, a gas inlet 01 and a gas outlet 02 intercommunicated with the internal space may be formed. The internal space of the chamber 100 is a space where a deposition process is performed on a substrate, and may be in a high-vacuum state to increase the purity and/or adhesive strength of a substance that is deposited by the deposition process and/or enhance the deposition efficiency. In the internal space of the chamber 100, an atomic layer deposition (ALD) process may be performed. In the internal space of the chamber 100, a chemical vapor deposition (CVD) process may be performed. For example, a pressure desired in the ALD process may be 10 torr and a pressure desired in the CVD process may be 90 torr. Since deposition speed may be faster in the CVD process than in the ALD process, the pressure desired in the CVD process may be higher than the pressure desired in the ALD process. However, these desired pressures are examples, and when the ALD process and the CVD process are performed simultaneously in one chamber, internal pressure may be controlled based on the pressure desired by the CVD process.

The gas supply pipe P1 according to some example embodiments may be connected to the gas inlet 01. The gas supply pipe P1 may be intercommunicated with the internal space of the chamber 100.

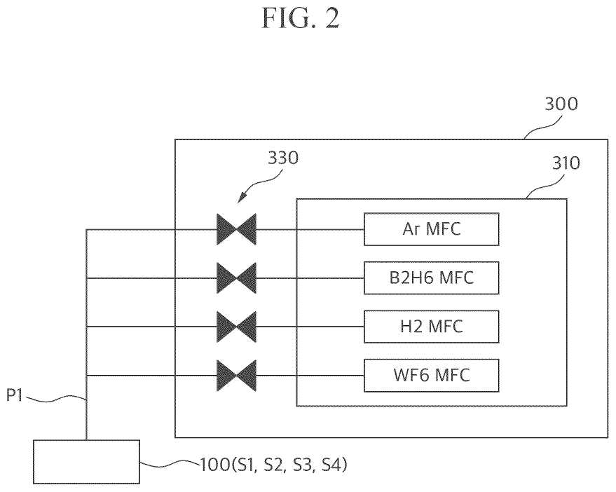

Referring to FIG. 2, the gas controller 300 according to some example embodiments may regulate the gas supplied to the internal space of the chamber 100 through the gas supply pipe P1. The gas controller 300 may include a gas storage part 310 and a gas control valve 330. The gas storage part 310 may store gas used in the deposition process. The gas storage part 310 may store various types of gas, and a plurality thereof may be arranged in response to the types of stored gas. For example, gas used in the deposition process may include Ar, B2H6, H2, WF6, and the like. More specifically, H2 and WF6 may be included when the CVD process is performed, and Ar, B2H6, H2, and WF6 may be included when the ALD process is performed. The gas storage part 310 may store Ar, B2H6, H2, and WF6 gases may be supplied in a constant mass flow rate through a mass flow controller (MFC). The gas storage part 310 may be formed as a pipe and may be also formed as a tank so that a larger amount of gas may be stored, and various forms that may provide a space for storing gas supplied through the MFC may be applied. The gas control valve 330 may be disposed between the gas storage part 310 and the gas supply pipe P1. When the gas control valve 330 is closed, the gas storage part 310 may be filled with various gases for performing each process by the MFC, and when the gas control valve 330 is opened, gas in the gas storage part 310 may be supplied to the internal space of the chamber 100 through the gas supply pipe P1. The gas controller 300 may regulate to the opening of the gas control valve 330 and control a type of gas supplied from the gas storage part 310. The gas controller 300 may include an ALD gas controller and a CVD gas controller. The CVD gas controller may maintain a constant pressure of gas supplied in the CVD process. The ALD gas controller may change a pressure of gas supplied in the ALD process. The gas controller 300 may be provided in each of stations S1 and S2 of the chamber 100 to be described below.

The gas exhaust pipe P2 according to some example embodiments may be connected to the gas outlet 02. The gas exhaust pipe P2 may be intercommunicated with the internal space of the chamber 100.

In the gas exhaust pipe P2 according to some example embodiments, a plurality of valves V may be disposed in series. The plurality of valves V may include a first valve V1 and a second valve V2. Each of the first valve V1 and the second valve V2 may open at least a portion of the gas exhaust pipe P2 between the chamber 100 and the vacuum pump 700. The first valve V1 and the second valve V2 may be provided inside the gas exhaust pipe P2 and regulate the area of gas flowing. The plurality of valves V may be throttle valves. The plurality of valves V may be butterfly valves. The plurality of valves V may be gate valves. However, the plurality of valves V may be valves that may regulate linearly the area of gas flowing inside the gas exhaust pipe P2 and are not limited to the above examples.

The vacuum pump 700 according to some example embodiments may pump gas from the internal space of the chamber 100 through the gas exhaust pipe P2. The vacuum pump 700 may have a constant output. For example, the output of the vacuum pump 700 may be maintained at 100 kiloliters per minute (kL/min) as constant.

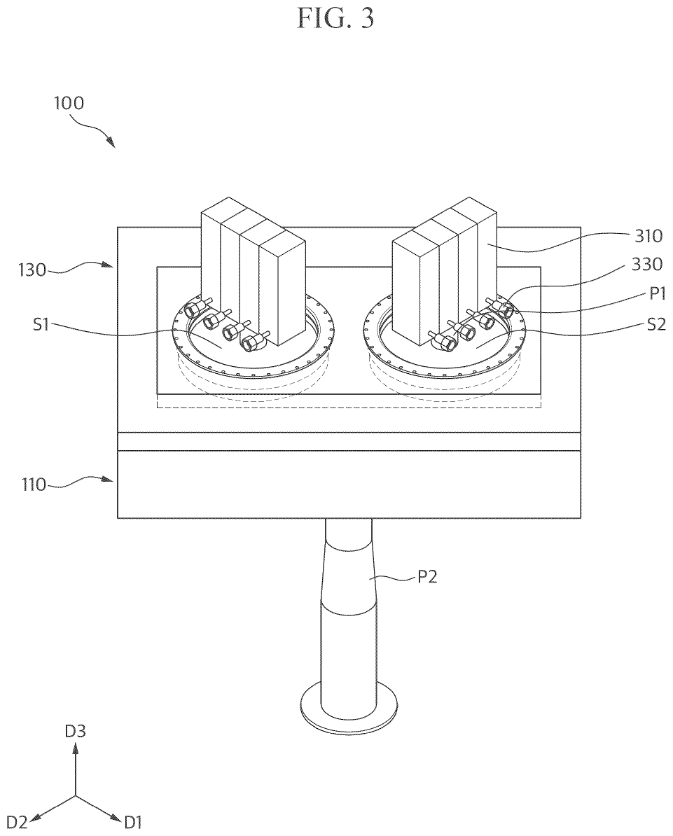

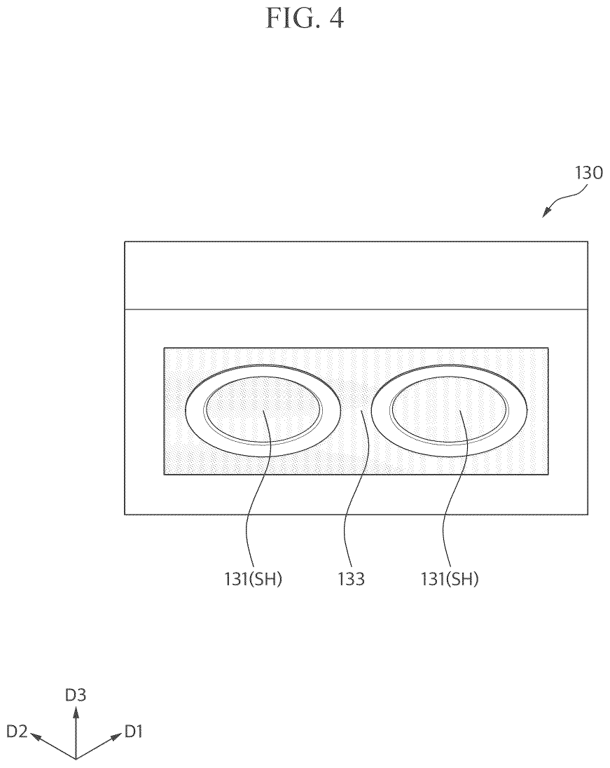

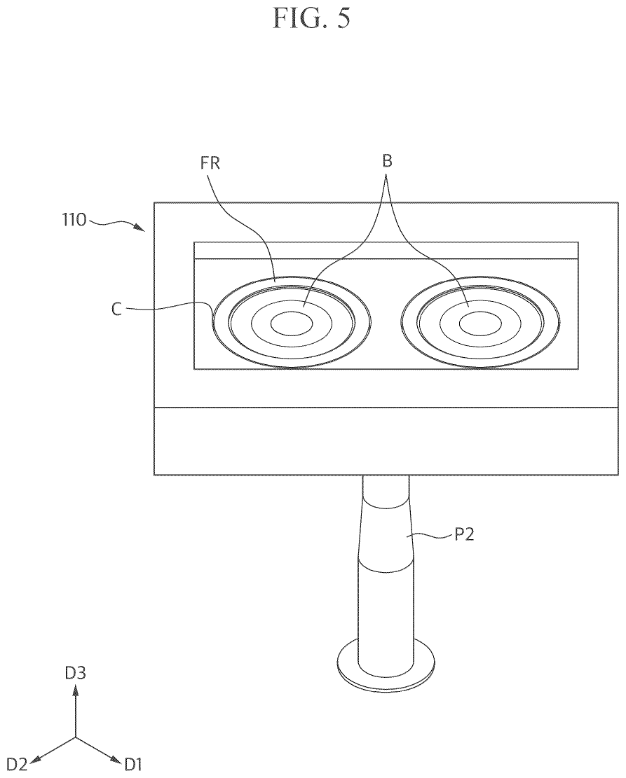

Hereinafter, a structure of the chamber 100 is described in more detail with reference to FIGS. 3 to 7. FIG. 3 is a diagram illustrating the chamber 100 included in the substrate treating apparatus 1 (see FIG. 1) according to some example embodiments. FIG. 4 is a diagram illustrating a gas supply unit 130 included in the substrate treating apparatus 1 according to some example embodiments. FIG. 5 is a diagram illustrating a substrate seating unit 110 included in the substrate treating apparatus 1 according to some example embodiments.

Referring to FIGS. 3 to 5, the chamber 100 may include the substrate seating unit 110 and the gas supply unit 130.

The chamber 100 according to some example embodiments may form an internal space in which a substrate is seated between the substrate seating unit 110 and the gas supply unit 130 which are disposed to face each other. The chamber 100 may include a plurality of stations S1 and S2 in which a substrate is individually seated on each station and a process is performed. For example, the plurality of stations may be provided as two, and the ALD process may be performed in station 1 (S1) and the CVD process may be performed in station 2 (S2).

The substrate seating unit 110 according to some example embodiments may include a substrate seating part B for a substrate seated and the gas outlet 02 (see FIG. 1) for exhausting gas from the internal space of the chamber 100. The substrate seating unit may include a focus ring FR. The focus ring FR may focus process gas to be deposited on a central portion of a substrate and simultaneously reduce and/or prevent an edge portion from contamination. The focus ring FR may include a ceramic material. The substrate seating part B may include a heater. The heater may be to create a high-temperature environment for the deposition process. The gas outlet 02 may be connected to the gas exhaust pipe P2. The substrate seating unit 110 may include a plurality of the substrate seating parts B where substrates are seated. For example, referring to FIG. 5, the substrate seating parts B may be provided as two. In this case, a separate process may be performed for each substrate seated on the different substrate seating parts B. The substrate seating unit 110 may include a substrate moving part (not shown) that moves a substrate between the plurality of the substrate seating parts B. The substrate moving part may move a substrate for which a process treatment is completed on one substrate seating part B to another substrate seating part B so that other processes may be performed for the substrate. However, the substrate moving part may not only move the substrate, but may include a mechanical component that may also move the plurality of the substrate seating parts B. For example, the substrate moving part may include a configuration for rotating the entire plurality of the substrate seating parts B with the gas supply unit 130 fixed, and may change a position of the substrate so that gas may be supplied to the substrate from another gas supply unit 130.

The gas supply unit 130 according to some example embodiments may be disposed to face the substrate seating unit 110. The gas supply unit 130 may be disposed to be spaced apart by a desired (and/or alternatively predetermined) distance in a direction perpendicular to a surface of a substrate and may move to be close to or spaced apart far from the substrate. The gas supply unit 130 may include the gas inlet 01. The gas supply unit 130 may be connected to the gas supply pipe P1. The gas supply unit 130 may include a shower head SH. The shower head SH may distribute gas substantially evenly on an entire area of the substrate at a consistent flow rate. The gas supply unit 130 may include a gas distributor 131 that distributes gas introduced from the gas inlet 01 formed in each position corresponding to the substrate seating parts B. A plurality of the gas distributors 131 may be provided. For example, referring to FIGS. 4 and 5, the gas distributors 131 may be formed as two corresponding to the number of the substrate seating parts B.

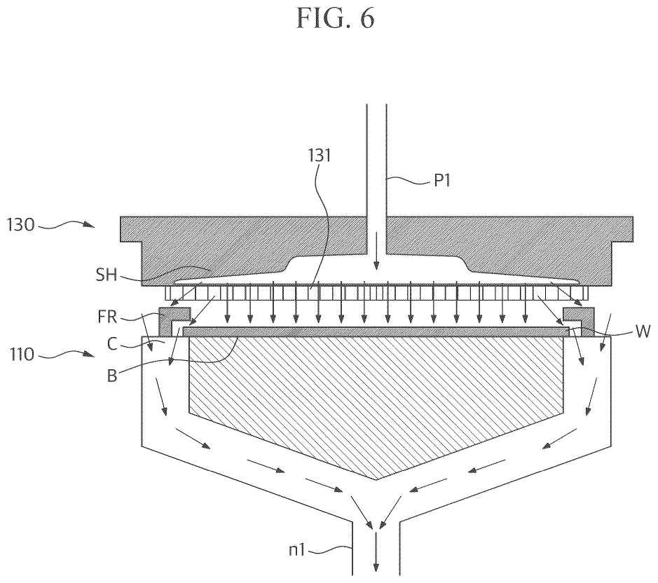

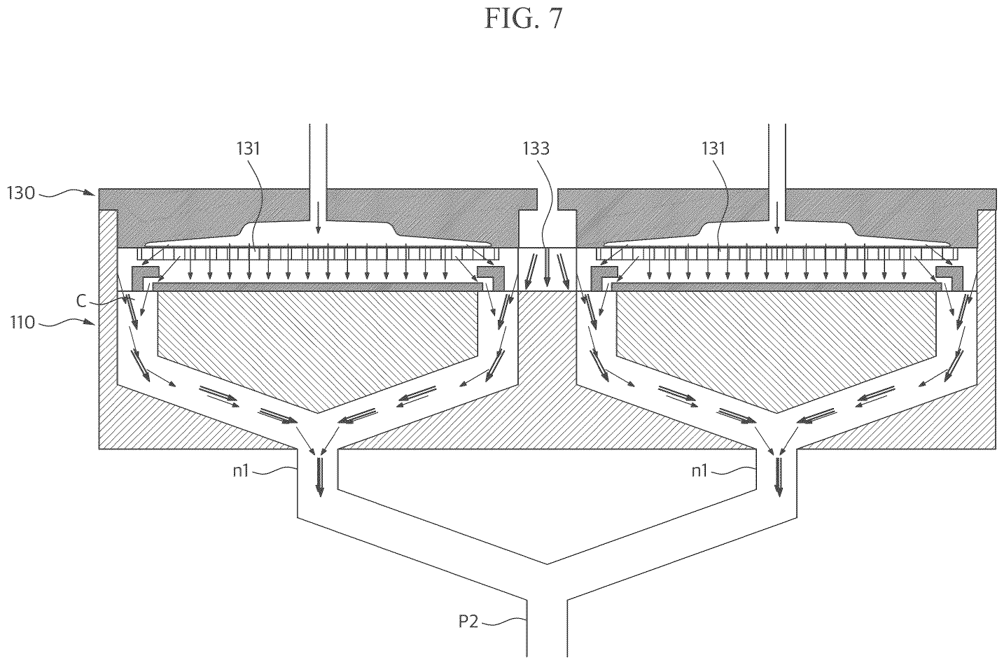

FIGS. 6 and 7 are diagrams illustrating a flow of gas in the chamber 100 included in the substrate treating apparatus 1 according to some example embodiments.

Referring to FIG. 6, the substrate seating part B and the gas distributor 131 according to some example embodiments may be disposed in a pair thereof. The pair of the substrate seating part B and the gas distributor 131 may represent the stations S1 and S2 described above. Therefore, FIG. 6 is a diagram illustrating a flow of gas in one station, and FIG. 7 is a diagram illustrating a flow of gas in a plurality of stations. The gas controller 300 (see FIG. 1) may provide control such that each different process gas is supplied to each gas distributor 131 corresponding to the substrate seating parts B and thus different processes may be performed for substrates seated on different substrate seating parts B.

Referring to FIGS. 6 and 7, gas distributed from the gas distributor 131 may be pumped into a gas pumping part C provided around the substrate seating part B. The gas pumped into the gas pumping part C may be gathered in a primary gas gathering part n1. The gas gathered in the primary gas gathering part n1 may be gathered in the gas exhaust pipe P2 with gas gathered in a neighboring primary gas gathering part n1 and may be pumped by the vacuum pump and exhausted.

The gas supply unit 130 according to some example embodiments may include a curtain part 133 disposed between the plurality of the gas distributors 131 in order for gases distributed from the plurality of the gas distributors 131 not to be supplied and mixed toward the substrate seating part B other than each corresponding substrate seating part B. The curtain part 133 may be arranged so that a plurality of fine holes disposed sequentially divide the plurality of the gas distributors 131 from each other and may distribute argon to form an argon (Ar) curtain between the plurality of the gas distributors 131. The argon gas delivered by the curtain part 133 may be pumped into the gas pumping part C and, similarly to the gas distributed from the gas distributor 131, may be gathered as flowing the primary gas gathering part n1 and the gas exhaust pipe P2 in sequence. The different gases distributed by the plurality of the gas distributors 131, even though leaving out of each station, may be pumped into the gas pumping part C and released with the argon gas distributed by the curtain part 133, thus being reduced and/or prevented from mixture and supply into a substrate of other stations.

In the chamber 100 according to some example embodiments, the ALD process and the CVD process may be performed simultaneously. On substrates seated on the plurality of the substrate seating parts B, gas released from the gas distributor 131 provided in a corresponding position may be distributed and each deposition process may be performed individually. For example, on one substrate seating part B, the ALD process may be performed, and on another substrate seating part B, the CVD process may be performed. These processes may be used for a process of depositing tungsten on a space resulting from high aspect ratio contact (HARC) etching. Accordingly, even while different processes are performed in the internal space of the identical chamber, air curtains formed through the curtain part 133 may make process gases not mix with each other.

In addition, when a process falls within processes that are sequentially treated in phases, processes may be performed consecutively by moving a substrate for which a process is ended from the substrate seating part B where the previous process is performed to the substrate seating part B where a following process is performed through the substrate moving part (not shown). However, in the deposition process such as the ALD and CVD processes described above, maintaining the pressure of internal space as constant may be a key element for obtaining the high-quality products of deposition. However, while the ALD process and the CVD process are performed simultaneously in the internal space of one chamber 100, time points in which gas is supplied vary for each process and the types of gas supplied are also various, and thus pressures in the internal space of the chamber 100 may be controlled. In particular, releasing processing gas and purging gas may be performed repeatedly in the ALD process. Accordingly, since the type and amount of gas exhausted during a process vary and gas is supplied not consecutively but as repeating supply and cutoff, the internal pressure of the chamber 100 may change during the process as long as an output of the vacuum pump is maintained as constant. Therefore, controlling the internal pressure of the chamber 100 is to be conducted precisely and with a fast response time. The valves facilitating the control of the internal pressure of the chamber 100 are described below in more detail.

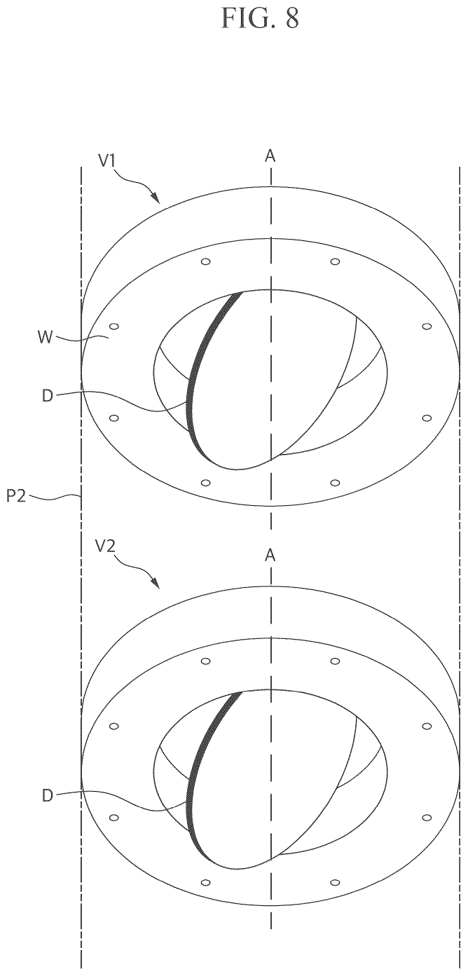

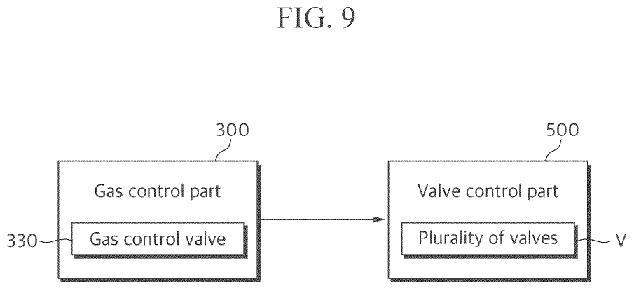

FIG. 8 is a diagram illustrating a plurality of valves included in a substrate treating apparatus according to some example embodiments. FIG. 9 is a flow chart illustrating a relationship between a gas controller and a valve controller included in a substrate treating apparatus according to some example embodiments.

Referring to FIGS. 8 and 9 together with FIG. 1, the substrate treating apparatus 1 according to some example embodiments may include the plurality of valves V and a valve controller 500.

The plurality of valves V according to some example embodiments may be disposed in series in the gas exhaust pipe P2. The plurality of valves V may include the first valve V1 and the second valve V2. The plurality of valves V may open at least a portion of the gas exhaust pipe P2 between the chamber 100 and the vacuum pump 700. Each of the plurality of valves V may have a degree of opening varied linearly in a range of greater than 30% and less than 60%. However, the degree of opening for each of the plurality of valves V may not always be varied in a range of 30% to 60% at every time point during a process. In other words, during the process, an opening position of the first valve V1 may be fixed at a desired (and/or alternatively predetermined) opening position between 0 to 100% and an opening position of the second valve V2 may be varied between 30 to 60%, or alternatively, the opening position of the first valve V1 may be varied between 30 to 60% and the opening position of the second valve V2 may be fixed at a desired (and/or alternatively predetermined) opening position between 0 to 100%. The plurality of valves V may be throttle valves. The plurality of valves V may be butterfly valves. However, the plurality of valves V may be valves that may regulate linear degrees of opening and are not limited to the above example embodiments.

The plurality of valves V according to some example embodiments may include an inner wall W, a rotational axis A, and a plate D. The inner wall W may be a cylindrical inner wall that is disposed within an inner circumference of the gas exhaust pipe P2. The rotational axis A may traverse a center of the gas exhaust pipe P2. The plate D may rotate on the rotational axis A within the inner wall W.

The valve controller 500 according to some example embodiments may regulate a degree of opening for the plurality of valves V. The valve controller 500 may vary linearly each degree of opening for the plurality of valves V in a range of greater than 30%. The valve controller 500 may vary linearly each degree of opening for the plurality of valves V in a range of less than 60%.

The valve controller 500 according to some example embodiments may vary the degree of opening for the plurality of valves V in response to a supply of the gas controller 300. The degree of opening for the plurality of valves V may be proportionate to a supply of gas supplied to the chamber 100. When an amount of gas supplied by the gas controller 300 increases, the valve controller 500 may increase the degree of opening for the valves V. The valve controller 500 may include an actuator that rotates the plate D on the rotational axis A of the valves V and an electrical control part that sends electrical signals to the actuator.

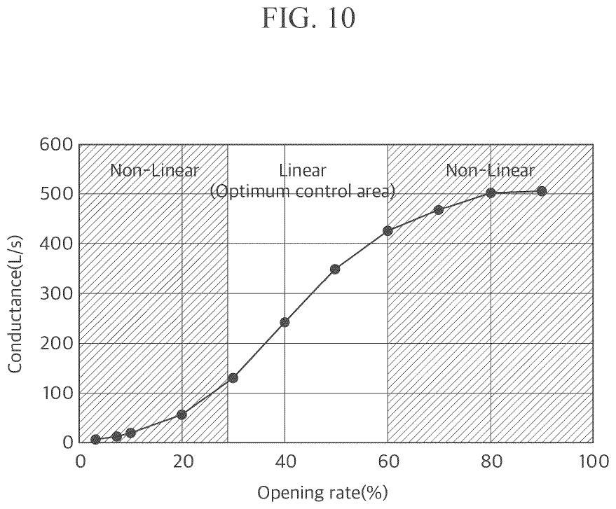

According to the configurations of some example embodiments, a flow rate of gas flowing through the gas exhaust pipe P2 may be controlled based on linear opening position of the valves V, leading to improved control of the internal pressure of the chamber 100, which is described below in more detail with reference to FIGS. 10 to 12.

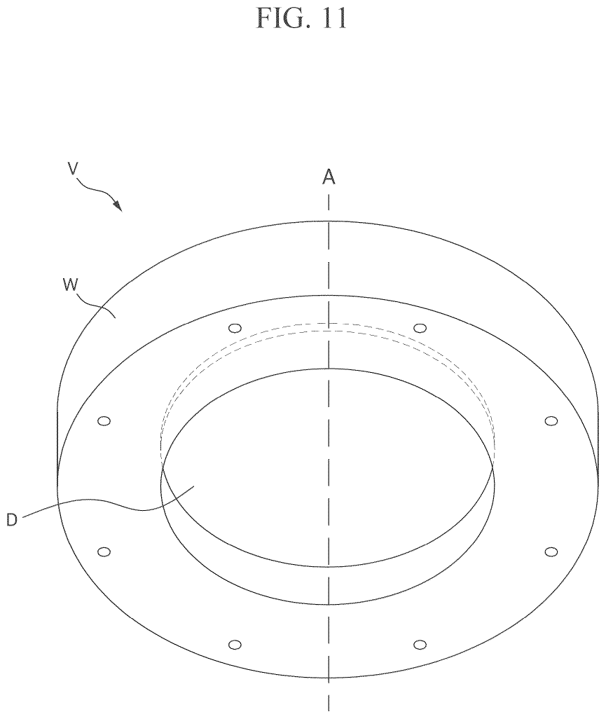

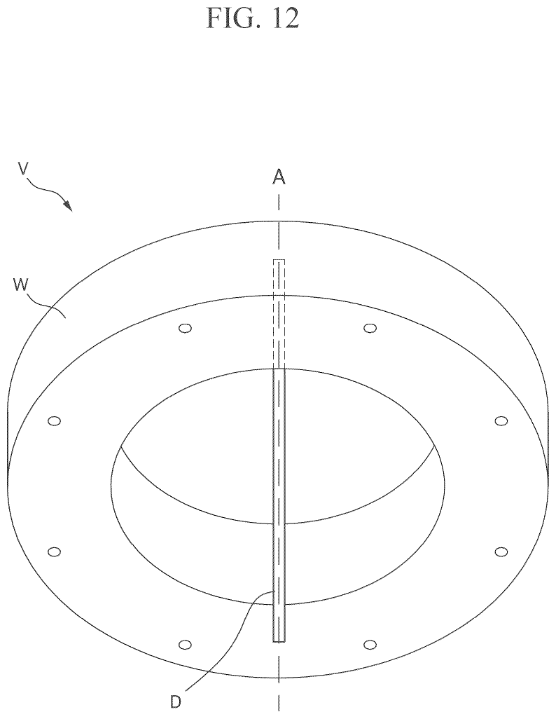

FIG. 10 is a graph illustrating a flow rate change depending on a valve opening position. FIG. 11 is a diagram illustrating a valve with a 0% valve opening position. FIG. 12 is a diagram illustrating a valve with a 100% valve opening position.

Referring to FIG. 10, a flow rate of gas flowing through the gas exhaust pipe P2 moves about linearly in a range of 30 to 60% opening position. FIG. 11 illustrates a 0% opening position of the valve V and the completely closed valve V, where an angle between the inner wall W and the plate D is 0°, and FIG. 12 illustrates a 100% opening position of the valve V, where an angle between the inner wall W and the plate D is 90°. An opening position may be defined as a relative ratio to 90° of an angle between the inner wall W and the plate D. For example, when the angle between the inner wall W and the plate D is 45°, the opening position may be 50%, and when the angle between the inner wall W and the plate D is 60°, the opening position may be 66.6%. In a specific section (for example, a section of 0 to 30% opening position) in which the gas exhaust pipe P2 starts to be opened by rotation of the plate D in a state of a 0% opening position as the gas exhaust pipe P2 is completely blocked by the plate D of the valve V and a specific section (for example, a section of 60 to 100% opening position) in which the gas exhaust pipe P2 is completely opened by the valve V as the angle between the inner wall W and the plate D approaches 90°, a section in which an opening position of the valve V and a flow rate of gas are not linearly controlled may be generated as a flow of gas is influenced by a pressure difference inside the gas exhaust pipe P2 generated as a boundary of the plate D, a flow velocity of gas, friction generated between gas and the inner circumferential surface of the gas exhaust pipe P2, the plate D, and the rotational axis A. Therefore, the control of a gas flow rate within the gas exhaust pipe P2 may be conducted in a range of 30 to 60% opening position of the valve V.

Hereinafter, the range of 30 to 60% opening position in which a flow rate of gas flowing through the gas exhaust pipe P2 is controlled about linearly is referred to as an optimum control area. As described above, since the type and amount of gas exhausted during the processes vary when the ALD process and the CVD process are performed simultaneously in the internal space of the chamber 100, it may be difficult to maintain a constant internal pressure of the chamber 100. In particular, it may be further difficult when a flow rate regulated according to opening position of the valves V does not move linearly. In addition, when the valve V is provided in one alone, the flow rate of gas flowing through the gas exhaust pipe P2 is regulated by one variable and thus may lack linear movements. In this case, the plurality of valves V may be disposed in series and an opening position of each valve V1 and V2 may be controlled within the range of the optimum control area.

Furthermore, when one valve is provided alone, the optimum control area may be 30% to 60% based on a whole pump performance and a twofold difference is generated between a desired minimum value and a desired maximum value in the optimum control area, however, when two valves are provided, the optimum control area may be 9% to 36% and a quadruple difference is generated between a desired minimum value and a desired maximum value in the optimum control area. In other words, by disposing the plurality of valves V in series, a flow rate of gas may be controlled more closely. However, since a maximum desired value of the opening position of the valves V is decreased from 60% to 36%, a sufficient output of the vacuum pump may not be transferred to the chamber. However, by enhancing the output or performance of the vacuum pump 700, a relative regulation range of the optimum control area may be increased, and movements of the flow rate of gas flowing through the gas exhaust pipe P2 according to the regulation of the opening position of the valves V may be controlled as more linear. For example, when a relative pressure desired in the internal space of the chamber 100 based on a performance of the vacuum pump 700 is 40 torr, by setting the performance of the vacuum pump to 200 kL/min providing two valves V, the relative pressure of the chamber 100 based on the performance of the vacuum pump 700 may be regulated linearly between 18 torr to 72 torr.

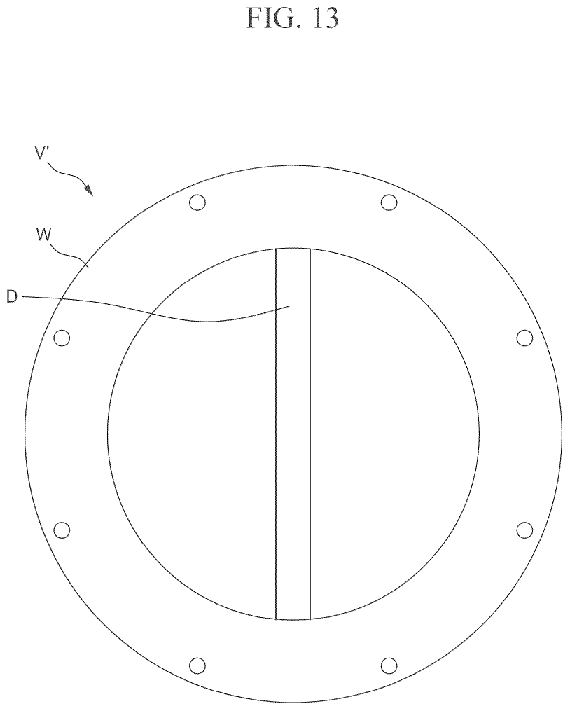

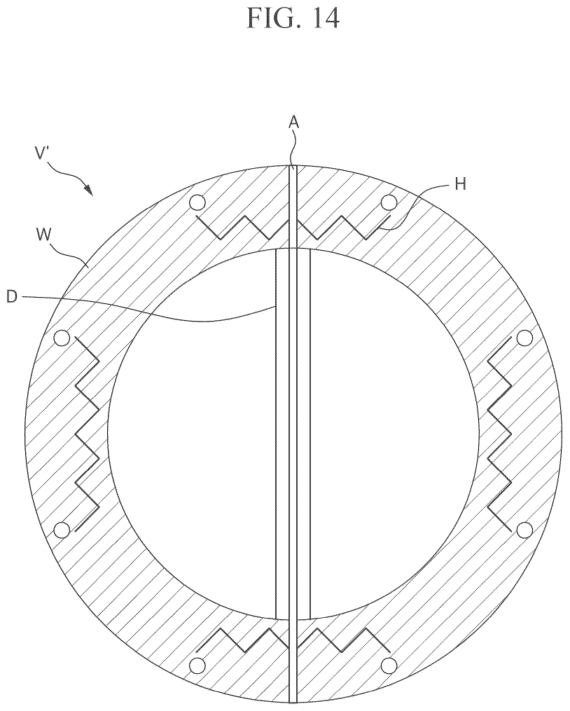

FIGS. 13 and 14 are diagrams illustrating a valve V′ included in a substrate treating apparatus according to some example embodiments. FIG. 13 illustrates a front view of the valve V′ included in a substrate treating apparatus according to some example embodiments. FIG. 14 illustrates a cross-sectional view of the valve V′ included in a substrate treating apparatus according to some example embodiments.

Referring to FIGS. 13 and 14, a plurality of valves V′ may further include a heater H with a cylinder shape which is disposed in the inner wall W. The heater H may be accommodated inside the inner wall W. The rotational axis A may be disposed to traverse the heater H. The plate D may receive heat transferred from the heater H through the rotational axis A.

For example, when process gas used in the CVD process is exhausted through the gas exhaust pipe P2, process byproducts may be included and exhausted together, and as the temperature of gas decreases during exhaust, the process byproducts may be deposited on the inner wall W of the valve V′ or the plate D. This may be why an opening position of the valve V′ and an actual opening position of the gas exhaust pipe P2 become different and in turn a flow rate of gas differs from intended.

Therefore, by heating the inner wall W, the rotational axis A, and the plate D through the heater H and reducing and/or minimizing a reduction in temperature of the exhausted gas, substances included in the gas exhausted from the internal space of the chamber 100 may be effectively reduced and/or prevented from depositing in the valve V′. In addition, a configuration of the thicker rotational axis or plate D may increase heat capacity of the valve V′ and increase (and/or maximize) the above feature.

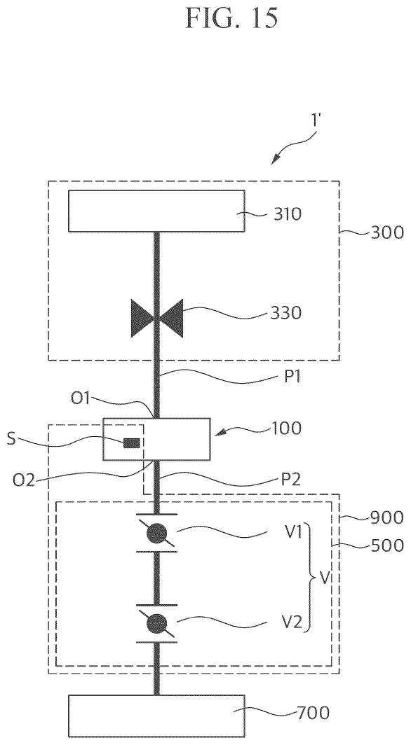

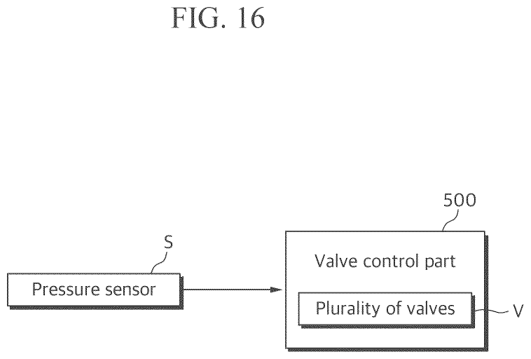

FIG. 15 schematically illustrates a substrate treating apparatus according to some example embodiments. FIG. 16 is a flow chart illustrating a relationship between a pressure sensor and a valve controller included in a substrate treating apparatus according to some example embodiments.

Referring to FIGS. 15 and 16, a substrate treating apparatus l′ according to some example embodiments may include the chamber 100, the gas supply pipe P1, the gas controller 300, the gas exhaust pipe P2, the vacuum pump 700, the plurality of valves V, and a pressure controller 900. Describing the remaining elements excluding the pressure controller 900 may be substituted with the above descriptions.

The pressure controller 900 according to some example embodiments may include a pressure sensor S and the valve controller 500.

The pressure sensor S according to some example embodiments may measure pressure in the internal space of the chamber 100. The valve controller 500 may vary the degree of opening for the plurality of valves V depending on a measurement result of the pressure sensor S.

The valve controller 500 according to some example embodiments may close the plurality of valves V more than a current state when a pressure less than a preset pressure is sensed in the pressure sensor S. In this case, the valve controller 500 may stop closing the valves V when the preset pressure is measured in the pressure sensor S.

The valve controller 500 according to some example embodiments may open the plurality of valves V more than a current state when a pressure higher than a preset pressure is sensed in the pressure sensor S. In this case, the valve controller 500 may stop opening the valves V when the preset pressure is measured in the pressure sensor S.

In other words, the valve controller 500 may vary the degree of opening for the plurality of valves V depending on a result of measuring pressure in the internal space of the chamber 100, which is measured by the pressure sensor S in order to maintain the pressure of the internal space of the chamber 100 as constant.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some example embodiments of the present disclosure are described above with reference to the appended drawings, the present disclosure is not limited to the example embodiments presented and may be implemented in various different forms, and it will be apparent to those of ordinary skill in the art to which the present disclosure pertains that other specific forms may be implemented without changing the technical spirit and essential features of the present disclosure. Therefore, the example embodiments described above are not to be construed as limiting the present disclosure.

What is claimed is:

1. A substrate treating apparatus comprising:
a chamber including
an internal space for processing a substrate, and
a gas inlet and a gas outlet configured to be intercommunicated with the internal space;
a gas supply pipe connected to the gas inlet;
a gas controller configured to regulate a supply gas to the internal space of the chamber through the gas supply pipe;
a gas exhaust pipe connected to the gas outlet;
a vacuum pump configured to pump gas from the internal space of the chamber through the gas exhaust pipe;
a plurality of valves in series in the gas exhaust pipe configured to open at least a portion of the gas exhaust pipe between the chamber and the vacuum pump; and
a valve controller configured to regulate a degree of opening for each valve of the plurality of valves,
wherein the valve controller is configured to vary the degree of opening for each valve of the plurality of valves in response to an amount of the supply gas delivered by the gas controller.

2. The substrate treating apparatus of claim 1, wherein the valve controller is configured to vary the degree of opening for each valve of the plurality of valves during a substrate treating process in a range of greater than 30 percent (%) to less than 60%.

3. The substrate treating apparatus of claim 1, wherein the plurality of valves include at least one of a throttle valve and a butterfly valve.

4. The substrate treating apparatus of claim 3, wherein
the butterfly valve includes
an inner wall that is cylindrical and within an inner circumference of the gas exhaust pipe,
a rotational axis traversing the gas exhaust pipe, and
a plate configured to rotate on the rotational axis within the inner wall.

5. The substrate treating apparatus of claim 4, wherein
the butterfly valve further includes a heater that is cylindrical and in the inner wall,
wherein the rotational axis traverses the heater, and
the plate is configured to receive heat transferred from the heater through the rotational axis.

6. The substrate treating apparatus of claim 1, wherein during a substrate treating process, the plurality of valves have a different degree of opening or a same degree of opening.

7. The substrate treating apparatus of claim 1, wherein the vacuum pump has a constant output.

8. The substrate treating apparatus of claim 1, wherein, in the internal space of the chamber, different processes are performed simultaneously.

9. The substrate treating apparatus of claim 8, wherein the different processes includes a chemical vapor deposition (CVD) process and an atomic layer deposition (ALD) process, and
wherein the gas controller includes
a CVD gas controller configured to control gas in the CVD process; and
an ALD gas controller configured to control gas in the ALD process.

10. The substrate treating apparatus of claim 9, wherein the CVD gas controller is configured to maintain a constant pressure of gas supplied in the chamber for performing the CVD process.

11. The substrate treating apparatus of claim 9, wherein the ALD gas controller is configured to regulate a pressure of gas supplied in the chamber for performing the ALD process.

12. The substrate treating apparatus of claim 11, wherein the valve controller is configured to vary the degree of opening for each valve of the plurality of valves in response to a gas pressure being changed by the ALD gas controller.

13. A substrate treating apparatus comprising:
a chamber including
an internal space for processing a substrate, and
a gas inlet and a gas outlet configured to be intercommunicated with the internal space;
a gas supply pipe connected to the gas inlet;
a gas controller configured to regulate a supply gas to the internal space of the chamber through the gas supply pipe;
a gas exhaust pipe connected to the gas outlet;
a vacuum pump configured to pump gas from the internal space of the chamber through the gas exhaust pipe;
a plurality of valves in series in the gas exhaust pipe configured to open at least a portion of the gas exhaust pipe between the chamber and the vacuum pump; and
a valve controller configured to regulate a degree of opening for each valve of the plurality of valves,
wherein, in the internal space of the chamber, a plurality of processes are performed simultaneously,
the plurality of processes includes a CVD process and an ALD process,
the gas controller includes
a CVD gas controller configured to control gas in the CVD process, and
an ALD gas controller configured to control gas in the ALD process,
the CVD gas controller is configured to maintain a constant pressure of gas supplied in the chamber for performing the CVD process,
the ALD gas controller is configured to regulate a pressure of gas supplied in the chamber for performing the ALD process, and
the valve controller is configured to vary the degree of opening for each valve of the plurality of valves in response to a gas pressure being changed by the ALD gas controller.

14. A substrate treating apparatus comprising:
a chamber including
an internal space for processing a substrate, and
a gas inlet and a gas outlet configured to be intercommunicated with the internal space;
a gas supply pipe connected to the gas inlet;
a gas controller configured to regulate a supply gas to the internal space of the chamber through the gas supply pipe;
a gas exhaust pipe connected to the gas outlet;
a vacuum pump configured to pump gas from the internal space of the chamber through the gas exhaust pipe;
a first valve in the gas exhaust pipe, the first valve configured to open at least a portion of the gas exhaust pipe between the chamber and the vacuum pump;
a second valve in series with the first valve, the second valve configured to open at least a portion of the gas exhaust pipe between the chamber and the vacuum pump; and
a pressure controller configured to regulate pressure in the internal space of the chamber,
wherein the pressure controller includes
a pressure sensor configured to measure a pressure in the internal space of the chamber, and
a valve controller configured to vary a degree of opening of the second valve in response to a measurement result of the pressure sensor.

15. The substrate treating apparatus of claim 14, wherein the valve controller is configured to reduce the degree of opening of the second valve in response to a pressure less than a preset pressure being sensed by the pressure sensor.

16. The substrate treating apparatus of claim 15, wherein the valve controller is configured to reduce the degree of opening of the second valve in response to a pressure greater than a preset pressure being sensed by the pressure sensor.

17. The substrate treating apparatus of claim 14, wherein the valve controller is configured to vary a degree of opening for each of the first valve and the second valve during a substrate treating process in a range of greater than 30% to less than 60%.

18. The substrate treating apparatus of claim 14, wherein
at least one of the first valve and the second valve includes
an inner wall that is cylindrical and within an inner circumference of the gas exhaust pipe,
a rotational axis traversing the gas exhaust pipe, and
a plate configured to rotate on the rotational axis within the inner wall.

19. The substrate treating apparatus of claim 14, wherein a degree of opening of at least one of the first valve and the second valve is proportionate to a supply of gas supplied to the chamber.

20. The substrate treating apparatus of claim 14, wherein the first valve and the second valve have a different degree of opening.
